(19) United States
(12) Patent Application Publication
(10) Pub. No.: US 2010/0126669 A1
(43) Pub. Date: May 27, 2010

(54) VACUUM TREATMENT APPARATUS

(75) Inventors: Akira Kumagai, Kawasaki-shi (JP); Keiji Ishibashi, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/597,804

(22) PCT Filed: Apr. 24, 2008
(86) PCT No.: PCT/JP2008/057892

§ 371 Date: Jan. 6, 2010

(30) Foreign Application Priority Data
May 8, 2007 (JP) 2007-123141

(51) Int. Cl. C23C 14/50; C23C 16/458; H01L 21/306

(52) U.S. Cl. 156/345.51; 118/728; 204/298.15

(57) ABSTRACT

Provided is a vacuum treatment device capable of uniformly treating the whole of a substrate in a vacuum container. In the vacuum treatment device in which the substrate is placed and held in the recess of a substrate holder, the difference between the heights of the surface of the substrate holder and the surface of the substrate to be treated is set to be equal to or shorter than 0.2 mm, and the distance between the side surface of the substrate and the inner surface of the recess of the substrate holder is set to be equal to or shorter than 5 mm.

### TECHNICAL FIELD

The present invention relates to a vacuum treatment apparatus that performs, for example, a film forming process or an etching process on a substrate to be processed in a vacuum chamber, such as a CVD (chemical vapor deposition) apparatus or a sputtering apparatus used for, for example, a process of manufacturing a semiconductor device.

### BACKGROUND ART

For example, Patent Document 1 discloses a CVD apparatus as a film forming apparatus using chemical vapor deposition. As described in Patent Document 1, in the film forming apparatus, a film forming substrate is placed on a substrate holding mechanism, that is, a substrate holder, and a film is formed on the substrate.

[Patent Document 1] JP-A-6-256958

### DISCLOSURE OF THE INVENTION

### Problems to be Solved by the Invention

As in the related art, when the film forming substrate is placed on the substrate holder and a film is formed thereon, the thickness of the film at the edge of the substrate is about 20% more than that of the film at the center of the substrate, and a film thickness uniformity is about ±9%, which does not satisfy industrial requirements. The industrially required film thickness uniformity in the plane of the substrate depends on the purpose of use, and is generally ±5% or less for application in electronic devices. Where the maximum value of measured values is referred to as Max, the minimum value thereof is referred to as Min, and the average value thereof is referred to as Ave, the film thickness uniformity (%) described herein is calculated by Expression 1 given below:

((Max−Min)/Ave)×100. [Expression 1]

An object of the invention is to provide a film forming apparatus capable of solving the above-mentioned problems of the film thickness distribution with simple means and forming a film with a uniform thickness on the entire substrate. Another object of the invention is to provide a vacuum treatment apparatus capable of uniformly performing not only a film forming process but any process on the entire substrate in a vacuum chamber.

### Means for Solving the Problems

According to an aspect of the present invention, a vacuum treatment apparatus includes a substrate holder having a concave portion into which a substrate to be processed is placed and held. A distance between a side surface of the substrate and an inner side surface of the concave portion of the substrate holder is equal to or less than 5 mm, and a height difference between a surface to be processed of the substrate and a surface of the substrate holder surrounding the concave portion is equal to or less than 0.2 mm.

### EFFECTS OF THE INVENTION

According to the present invention, it is possible to uniformly process the center and the periphery of a substrate to be processed. In addition, according to the vacuum treatment apparatus of the invention, it is possible to use an apparatus of the related art by replacing a substrate holder according to the dimensions of a substrate to be processed. Therefore, it is possible to uniformly process a substrate without increasing a manufacturing cost. As a result, it is possible to improve manufacturing yield in a process of manufacturing a semiconductor device or the like using such an apparatus, and provide an inexpensive semiconductor device.

### BRIEF DESCRIPTION OF THE DRAWINGS

FIG. 1 is a cross-sectional view schematically illustrating the vicinity of the edge of a substrate for explaining the relationship between the substrate and a substrate holder according to the invention.

FIG. 2 is a graph illustrating the calculation results of a film thickness distribution in an apparatus according to the related art and a conceptual diagram illustrating the cause of thickness nonuniformity.

FIG. 3 is a cross-sectional view schematically illustrating a substrate holder according to embodiments of the invention.

FIG. 4 is a diagram illustrating a film thickness distribution according to an example of the invention.

### REFERENCE NUMERALS

1: Substrate
2: Substrate holder
3: Frame
4: Substrate transporting holder

### BEST MODE FOR CARRYING OUT THE INVENTION

Examples of a vacuum treatment apparatus according to the present invention include a CVD apparatus, a sputtering apparatus, and the like.

The inventors have conducted various film forming experiments in order to examine the cause of the thickness nonuniformity of the film at the edge of the substrate. The examination results proved that a stepped portion generated at the edge of the substrate causes the thickness nonuniformity. Specifically, when the periphery of a circular substrate having a thickness of 0.5 mm and a diameter of 100 mm is 0.5 mm lower than a film forming surface of the substrate, the film at the edge of the substrate has a large thickness. On the other hand, when the periphery of the substrate is 0.5 mm higher than the film forming surface of the substrate, the film at the edge of the substrate has a small thickness. The difference between the thickness of the film at the edge of the substrate and the thickness of the film at the center of the substrate is about 20%, and the thickness nonuniformity caused by the stepped portion at the edge of the substrate occurs within the range of about 20 to 30 mm from the edge of the substrate toward the center thereof.

In a so-called remote plasma CVD apparatus, a deposition precursor generated in a gas phase is carried onto the substrate by a diffusion phenomenon to form a film. The formation of a film by the diffusion of the deposition precursor is calculated in a pseudo manner.

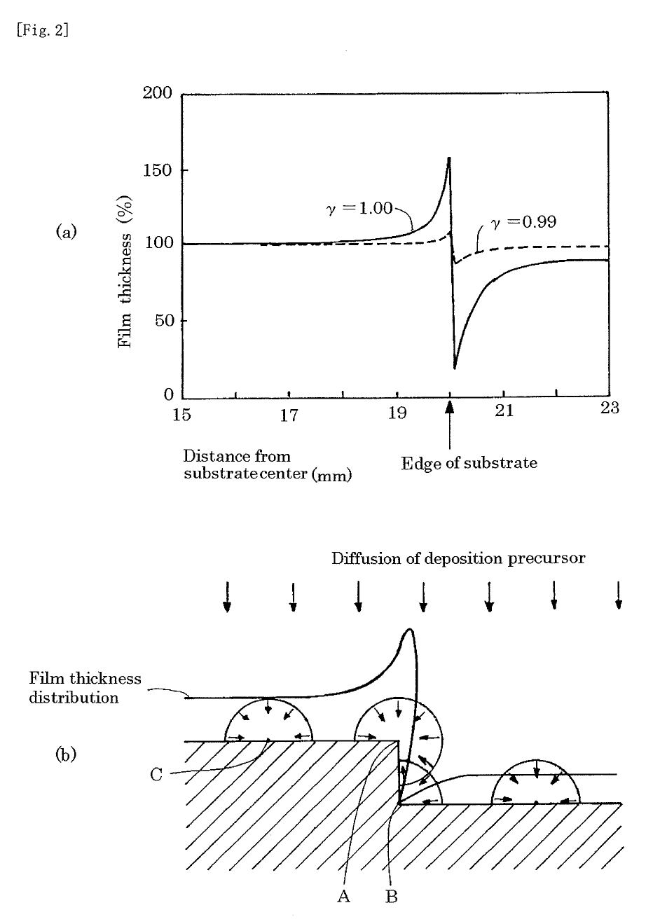

With respect to a case where the deposition precursor reaches a geometrical structure having a stepped portion by diffusion and a film is formed on the film forming surface of the substrate with the film forming surface being higher than the periphery of the substrate, the steady-state diffusion equation is solved in a two-dimensional plane to calculate a film thickness distribution. The calculation results are shown in FIG. 2(a). FIG. 2(a) shows the calculation results in two cases where an adhesion probability (γ) is 1.00 and 0.99. An adhesion probability of 1.00 means that the particles of the deposition precursors reaching the surface are completely adhered to the surface. As shown in FIG. 2(a), the calculation results are well matched with the tendency of the film thickness distribution obtained by the experiments.

In the case of diffusion, the concentration at a certain point on the substrate depends on the concentration in the periphery of the point. FIG. 2(b) is a conceptual diagram illustrating thickness nonuniformity caused by a stepped portion. The viewing angle of the upper end A of a stepped portion is wider than that of a flat portion C on the substrate, and the upper edge A can be supplied with particles in a wider range. In contrast, the lower edge B of the stepped portion has a narrow viewing angle due to the wall of the stepped portion. That is, a particle supply range is narrow. Therefore, it is considered that the thickness nonuniformity in a stepped region observed in the experiments is caused by the amount of particles supplied according to the magnitude of the viewing angle.

The inventors have examined step conditions in order to remove the thickness nonuniformity on the basis of the above-mentioned results, by which the invention is achieved. Specifically, the difference between the distance between the side surface of the substrate and the inner surface of a concave portion of a substrate holder and the height from the film forming surface of the substrate to the surface of the substrate holder surrounding the concave portion is defined, in a state where the substrate is placed in the concave portion of the substrate holder. In this way, it is possible to form a film with a uniform thickness on the film forming surface of the substrate. The invention is not limited to a case where a film is formed on the film forming surface of the substrate, but it can also be applied to a case where a surface treatment, such as an etching process, is performed on a surface to be treated of the substrate. According to the invention, the surface treatment can be uniformly performed on the substrate.

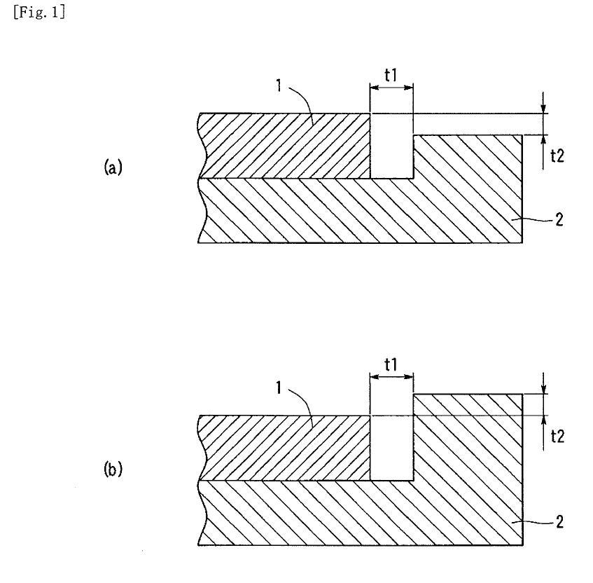

FIG. 1 is a cross-sectional view schematically illustrating the vicinity of an edge of a substrate held on a substrate holder in the apparatus according to the invention. In FIG. 1, reference numeral 1 denotes a substrate to be processed, and reference numeral 2 denotes a substrate holder. FIG. 1(a) shows a case in which the surface to be processed of the substrate 1 is higher than the surface of the substrate holder 2 surrounding a concave portion, and FIG. 1(b) shows a case in which the surface to be processed of the substrate 1 is lower than the surface of the substrate holder 2.

In the invention, a distance t1 between the side surface of the substrate 1 and the side surface of the concave portion of the substrate holder 2 is equal to or less than 5 mm, and a height difference t2 between the surface to be processed of the substrate 1 and the surface of the substrate holder 2 surrounding the concave portion is equal to or less than 0.2 mm. When a heat treatment is performed on the substrate, it is preferable that the distance t1 between the side surface of the substrate 1 and the side surface of the concave portion of the substrate holder 2 be equal to or less than 5 mm and the height difference t2 between the surface to be processed of the substrate 1 and the surface of the substrate holder 2 surrounding the concave portion be equal to or less than 0.2 mm during the treatment. That is, for example, when the substrate 1 and the substrate holder 2 are thermally expanded and the distance t1 is increased, the sizes of the substrate holder 2 and the substrate 1 are set such that the distance t1 before heating is less than 5 mm and the distance t1 after thermal expansion during the treatment will not exceed 5 mm. On the contrary, when the distance t1 is decreased by thermal expansion, it is preferable that the distance t1 before heating be set to be more than 0 mm such that the substrate 1 will not be damaged by being pressed by the substrate holder 2 due to thermal expansion during the treatment. Specifically, it is preferable that the distance t1 before heating is set to a value that can be reduced by thermal expansion and that will be reduced to exactly 0 mm after.

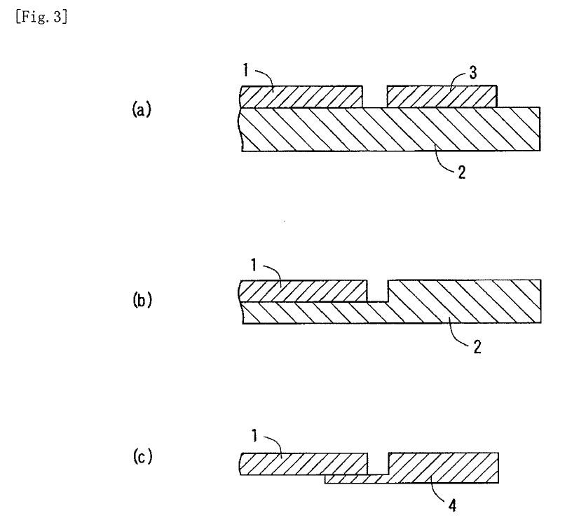

For example, when the substrate 1 has a diameter of 200 mm and is made of Si (thermal expansion coefficient=24×10⁻⁶/K) and the substrate holder 2 is made of SUS304 (thermal expansion coefficient=17.3×10⁻⁶/K) and has a shape as shown in FIG. 3(b), the diameter of the concave portion of the substrate holder 2 is increased by thermal expansion but the amount of thermal expansion of the substrate 1 is more than that of the substrate holder. As a result, the distance t1 is decreased by heating. Therefore, for example, when a heating temperature during the treatment is 300° C., the diameter of the concave portion of the substrate holder 2 is set to 200.374 mm and the distance t1 is set to 0.374 mm. In this case, when the heating temperature reaches 300° C., the distance t1 becomes approximately zero, and it is thus possible to prevent the damage of the substrate 1.

FIG. 3 illustrates a substrate holder according to embodiments of the invention. FIG. 3(a) shows an embodiment in which a frame 3 that surrounds the substrate 1 is mounted on a flat substrate holder 2 to obtain a structure corresponding to the invention. FIG. 3(b) shows an embodiment in which a concave portion is formed at the center of a flat substrate holder to place the substrate 1. FIG. 3(c) shows an embodiment in which a substrate transporting holder 4 is used to process a substrate and an opening that is used to lift up and remove the substrate from the holder 4 is formed at the center of the holder 4. The above-mentioned embodiments all satisfy the distance from the side surface of the substrate 1 and the height difference between the surfaces defined in the invention.

### EXAMPLES

A substrate transporting holder 4 in which a concave portion was formed at the center thereof and an outer circumferential portion had a large thickness to increase strength was manufactured. A TiN film was formed on a circular substrate 1 having a thickness of 0.5 mm and a diameter of 100 mm by a CVD method. The concave portion of the holder 4 had dimensions of t1=5 mm and t2=0.2 mm, where t1 and t2 are as defined in FIG. 1.

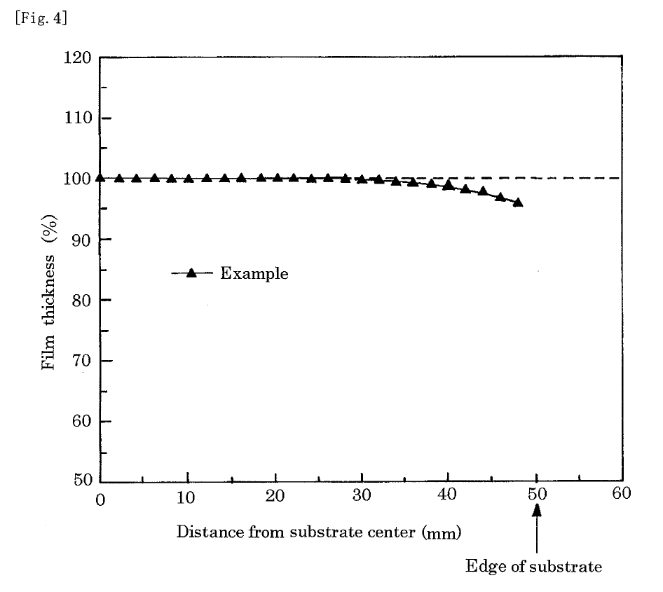

The thickness of the obtained TiN film was calculated from the sheet resistance measured by a four-probe method, and the results are shown in FIG. 4. In this example, the film thickness uniformity was about ±2.5% which was equal to or less than ±5%.

Then, substrates having thicknesses and diameters determined such that t1 and t2 shown in FIG. 1 satisfy the values shown in Table 1 during a film forming process when the substrates were held by the same substrate transporting holder 4 were manufactured, and TiN films were formed under the same conditions as described above. The thickness of the obtained TiN films was calculated from the sheet resistance measured by a four-probe method, and the results of the film thickness uniformity are shown in Table 1. In Table 1, a symbol ‘◯’ indicates that the film thickness uniformity is less than ±3%, a symbol ‘Δ’ indicates that the film thickness uniformity is ±3% or more and less than ±5%, and a symbol ‘X’ indicates that the film thickness uniforimity is equal to or more than ±5%. As shown in Table 1, when t1 is equal to or less than 5 mm and t2 is equal to or less than 0.2 mm, a good film thickness uniformity is obtained.

TABLE 1

t1(mm)

| t2(mm) | 3 | 5 | 7 | 10 |
|---|---|---|---|---|
| 0.1 | ◯ | ◯ | Δ | X |
| 0.2 | ◯ | ◯ | Δ | X |
| 0.3 | Δ | Δ | Δ | X |
| 0.4 | Δ | X | X | X |

1. A vacuum treatment apparatus comprising:
a substrate holder having a concave portion configured to hold a substrate to be processed,
wherein a distance between a side surface of the substrate and an inner side surface of the concave portion of the substrate holder is equal to or less than 5 mm, and
a height difference between a surface to be processed of the substrate and a surface of the substrate holder surrounding and the concave portion is equal to or less than 0.2 mm.

2. A CVD apparatus comprising:
a substrate holder having a concave portion configured to hold a substrate and a outer portion surrounding the concave portion,
wherein a distance between a side surface of the substrate and an inner side surface of the concave portion of the substrate holder is more than 0 mm and equal to or less than 5 mm,
and
a height difference between a surface of the substrate and a surface of the outer portion is equal to or less than 0.2 mm.

3. The CVD apparatus according to claim 2, wherein the substrate holder is made of stainless steel.

4. The CVD apparatus according to claim 2, wherein a length from an inner edge to an outer edge of the outer portion is equal to or more than 20 mm.
